(19) United States
(12) Patent Application Publication
(10) Pub. No.: US 2024/0270462 A1
(43) Pub. Date: Aug. 15, 2024

(54) THERMAL INSULATING SHRINK FILM WITH METALLIZED REFLECTIVE SURFACE

(71) Applicant: Naci Tamer ÖZERDEN, Istanbul (TR)

(72) Inventor: Naci Tamer ÖZERDEN, Istanbul (TR)

(21) Appl. No.: 18/567,043

(22) PCT Filed: Apr. 14, 2022
(86) PCT No.: PCT/TR2022/050334

§ 371 Date: Dec. 5, 2023

(30) Foreign Application Priority Data
Jun. 15, 2021 (TR) 2021/009784

(51) Int. Cl. B65D 65/16; B65D 75/00

(52) U.S. Cl. CPC B65D 65/16; B65D 75/002; B65D 2571/00024

(57) ABSTRACT

Disclosed is a thermal insulating shrink film having a polymer-based film layer with a metallized surface layer applied to at least one side of the polymer-based film layer.

### FIELD OF THE INVENTION

The present invention relates to packaging products.

More specifically, the invention relates to a thermal insulating shrink film with at least one metallized reflective surface.

### PRIOR ART

Today, standard shrink films do not provide thermal insulation, hence it is not possible to avoid reduced shelf lives and degradation of quality of products. Standard shrink films come with this fundamental drawback, while the present invention aims to extend shelf life and improve food safety by maintaining the temperature of the product for longer durations to eliminate this drawback.

For palletized heat-sensitive products, thermal insulated packaging materials are used in such a way as to wrap around the pallet. In such cases, a shrink film or a shrink hood film, in addition to thermal insulated pallet cover needs to be used. This leads to use of more consumables and additional labour.

Cold chain food products are exposed to temperature changes during storage, loading, unloading, holding and in-market operations. Various thermal insulation covers are used during these operations. The present invention aims to provide thermal insulation for these products during standard shrink operation without the need for such additional costs and handling expenses.

Shrink film is widely used in shipping of food products, and at its present state, it does not contribute to maintain original temperature of products for longer duration.

The present invention aims to contribute maintaining the quality of carbonated drinks in particular thanks to the protection offered against ultraviolet (UV) rays.

The invention also aims to prevent discoloration and material deformation of construction chemicals and materials, machinery and auto spare parts, etc. caused by solar rays in lengthy outdoor storage conditions in their shrink packaging.

The invention also aims to provide the same benefits to heat-sensitive products in the chemical and paint industry.

In conclusion, the drawbacks explained above and the shortcomings of the existing solutions to the problems have necessitated improvement in the related technical field.

### SUMMARY OF THE INVENTION

The present invention relates to a metallized shrink film and derivative products which satisfy the requirements listed above and to eliminate all disadvantages while bringing additional benefits to the technical field.

The primary object of the invention is to provide a thermal insulating shrink film with at least one metallized reflective surface. Hence, the shrink film with one or two metallized reflective surfaces will be used for packaging heat-sensitive products with thermal insulation. This will bring thermal insulation to shrink film packaging operations.

Another object of the invention is to provide a thermal insulating shrink film suitable for use across all fields of application of standard shrink films.

Another object of the invention is to provide a reflective surface on a standard shrink film not only to prevent the package from coming apart in all fields of application of standard shrink films, but also to maintain the ideal temperature range of the product for longer duration, thereby eliminating the need for additional insulating materials.

Another object of the invention is to provide a shrink film which maintains the temperature of the household or industrial food products in cold or warm areas for a longer time to extend the shelf life during storage and shipping and improve food safety. Therefore, it is aimed to eliminate the need for consumables for thermal insulation during the storage and shipping of food products.

Drawings below and the detailed description set out with reference to the accompanying drawings provide for a clearer understanding of the structural and characteristic properties and all benefits of the present invention; therefore, the evaluation needs to take these drawings and the detailed description into account.

### BRIEF DESCRIPTION OF THE DRAWINGS

FIG. 1 is a schematic cross-section view of a shrink film configuration according to prior art.

FIG. 2 is a schematic cross-section view of an embodiment of the invention.

FIG. 3 is a schematic cross-section view of another embodiment of the invention.

### LIST OF REFERENCE NUMERALS

1 Metallized shrink film
10 Polymer-based film layer
20 Metallized surface layer

### DETAILED DESCRIPTION OF THE INVENTION

In this detailed description, the metallized shrink film according to the invention is explained for better understanding of the subject in an unconstrained manner.

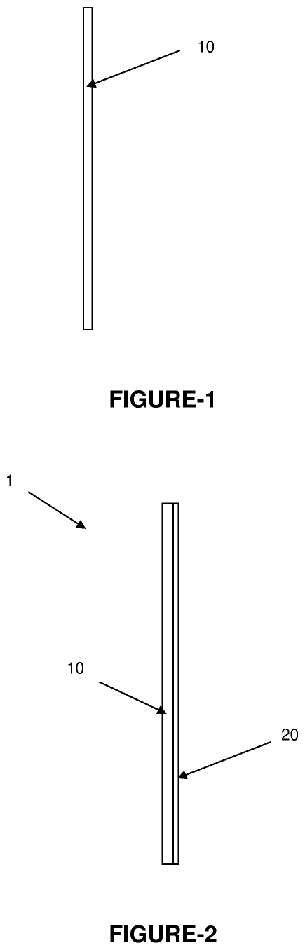

The invention relates to a composite metallized shrink film (1) with heat insulating properties obtained by metallization through applying metal vapor on one or two sides of a shrink film according to prior art as shown in FIG. 1.

The invention relates to a metallized shrink film (1) with polymer-based film layer (10), comprising a metallized surface layer (20) applied to at least one side of said polymer-based film layer (10) as shown in FIG. 2.

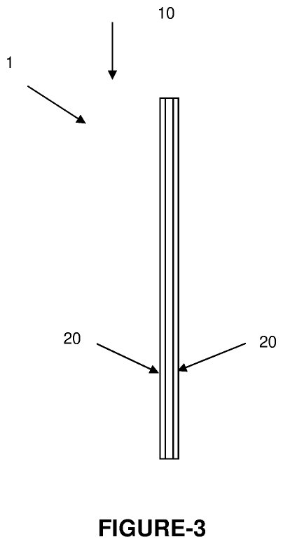

According to an embodiment of the invention, it comprises a metallized surface layer (20) applied to both sides of said polymer-based film layer (10) as shown in FIG. 3.

Said polymer-based film layer (10) is made of a polymer, preferably a polyethylene-based polymer.

Said metallized surface layer (20) is a metal-based layer obtained by metallization through applying a metal vapor, and preferably aluminum vapor to the polymer-based film layer (10).

An embodiment of the invention relates to a thermal insulating shrink film, characterized by functioning as both a standard shrink film in palletization of products and a thermal insulating pallet cover that protects the product against external weather conditions thanks to its metallized reflective surface.

The invention aims to provide a reflective surface on a standard shrink film through metallization operation not only to prevent the pallet from coming apart in all fields of application of standard shrink films, but also to maintain the original temperature of the product for a longer time, thereby eliminating the need for additional insulating materials.

1. A metallized shrink film having a polymer-based film layer, wherein a metallized surface layer is applied to at least one side of said polymer-based film layer.

2. The metallized shrink film according to claim 1, wherein a metallized surface layer is applied to both sides of said polymer-based film layer.

3. The metallized shrink film according to claim 1, wherein said polymer-based film layer is polyethylene-based polymer.

4. The metallized shrink film according to claim 1, comprising an aluminum-based metallized surface layer.

5. The metallized shrink film according to claim 2, wherein said polymer-based film layer is polyethylene-based polymer.
